(19) United States
(12) Patent Application Publication
(10) Pub. No.: US 2014/0252541 A1
(43) Pub. Date: Sep. 11, 2014

(54) SYSTEMS AND METHODS FOR POWER TRAIN ASSEMBLIES

(71) Applicant: GENERAL ELECTRIC COMPANY, Schenectady, NY (US)

(72) Inventors: Ivan Dimitrov Nanov, Plano, TX (US); John Frank Steel, Plano, TX (US)

(73) Assignee: GENERAL ELECTRIC COMPANY, Schenectady, NY (US)

(21) Appl. No.: 13/792,293

(22) Filed: Mar. 11, 2013

(51) Int. Cl. H01L 23/34; H05K 3/32

(52) U.S. Cl. CPC H01L 23/34; H05K 3/32
USPC 257/531; 257/713; 29/832

(57) ABSTRACT

A power train assembly is provided. The power train assembly includes a component package including a first transistor having a first gate, a first drain, and a first source, a second transistor having a second gate, a second drain, and a second source, and a thermal pad configured to dissipate heat generated in the component package, wherein the thermal pad is electrically coupled to the first source and the second drain. The power train assembly further includes a printed circuit board (PCB) electrically coupled to the component package, and an electrical component electrically coupled directly to the thermal pad, wherein the electrical component is external to the component package.

### BACKGROUND

The field of the embodiments described herein relates generally to power train assemblies, and more particularly, to the interconnection of component packages in power train assemblies.

At least some power converters include a component package having multiple transistors, such as semiconductor MOSFETs. Integration of multiple MOSFETs into a single package may reduce a parasitic inductance of connections between the transistors, allowing the transistors to be switched on and off more quickly. Reduced switch transition times allow operation at higher frequencies, which helps reduce the size of reactive components of the converter. The integration also reduces the resistance of the connections between the transistors, minimizing copper losses and improving efficiency. The integrated package also occupies less space, reducing costs, increasing power density, etc. However, the smaller footprint may require additional means to dissipate the amount of heat generated.

At least some component packages in power converters include a top side cooling tab. The cooling tab may be, for example, an exposed metal clip. In at least some component packages, the cooling tab functions solely to dissipate heat, and does not serve as an electrical connection used in the operation of the component package. Instead, in at least some known packages, the electrical connections are made through a printed circuit board.

### BRIEF DESCRIPTION

In one aspect, a power train assembly is provided. The power train assembly includes a component package including a first transistor having a first gate, a first drain, and a first source, a second transistor having a second gate, a second drain, and a second source, and a thermal pad configured to dissipate heat generated in the component package, wherein the thermal pad is electrically coupled to the first source and the second drain. The power train assembly further includes a printed circuit board (PCB) electrically coupled to the component package, and an electrical component electrically coupled directly to the thermal pad, wherein the electrical component is external to the component package.

In another aspect, a component package is provided. The component package includes a first transistor having a first gate, a first drain, and a first source, a second transistor having a second gate, a second drain, and a second source, and a thermal pad configured to dissipate heat generated in the component package, wherein the thermal pad is electrically coupled to the first source and the second drain and directly coupled to at least one additional electrical component.

In yet another aspect, a method of assembling a power train assembly is provided. The method includes electrically coupling a component package to a printed circuit board (PCB), the component package including a first transistor including a first gate, a first drain, and a first source, a second transistor including a second gate, a second drain, and a second source, and a thermal tab electrically coupled to the first source and the second drain. The method further includes electrically coupling an electrical component directly to the thermal tab, the electrical component external to the component package.

### BRIEF DESCRIPTION OF THE DRAWINGS

FIG. 1 is a schematic diagram of an exemplary power train assembly.

FIG. 2 is a circuit diagram of the power train assembly shown in FIG. 1.

FIG. 3 is a circuit diagram of an alternative power train assembly.

FIG. 4 is a diagram of the power train assembly shown in FIG. 1.

FIG. 5 is a diagram of an alternative power train assembly.

FIG. 6 is a diagram of an alternative power train assembly.

FIG. 7 is a diagram of an alternative power train assembly.

FIG. 8 is a diagram of an alternative power train assembly.

FIG. 9 is a diagram of an alternative power train assembly.

FIG. 10 is a diagram of an alternative power train assembly.

FIG. 11 is a circuit diagram of the power train assembly shown in FIG. 10.

FIG. 12 is a diagram of an alternative power train assembly.

FIG. 13 is a diagram of an alternative power train assembly.

FIG. 14 is a plan view of an alternative power train assembly.

FIG. 15 is a side view of the power train assembly shown in FIG. 14.

FIG. 16 is a flowchart of an exemplary method for assembling a power train assembly.

### DETAILED DESCRIPTION

Exemplary systems and methods for power train assemblies are described herein. A component package in a power train assembly includes a first transistor, a second transistor, and a thermal pad. The thermal pad is electrically coupled to the first and second transistors. An additional electrical component, such as an inductor or a transformer winding, is also electrically coupled to the thermal pad directly, without being coupled to the thermal pad through a PCB.

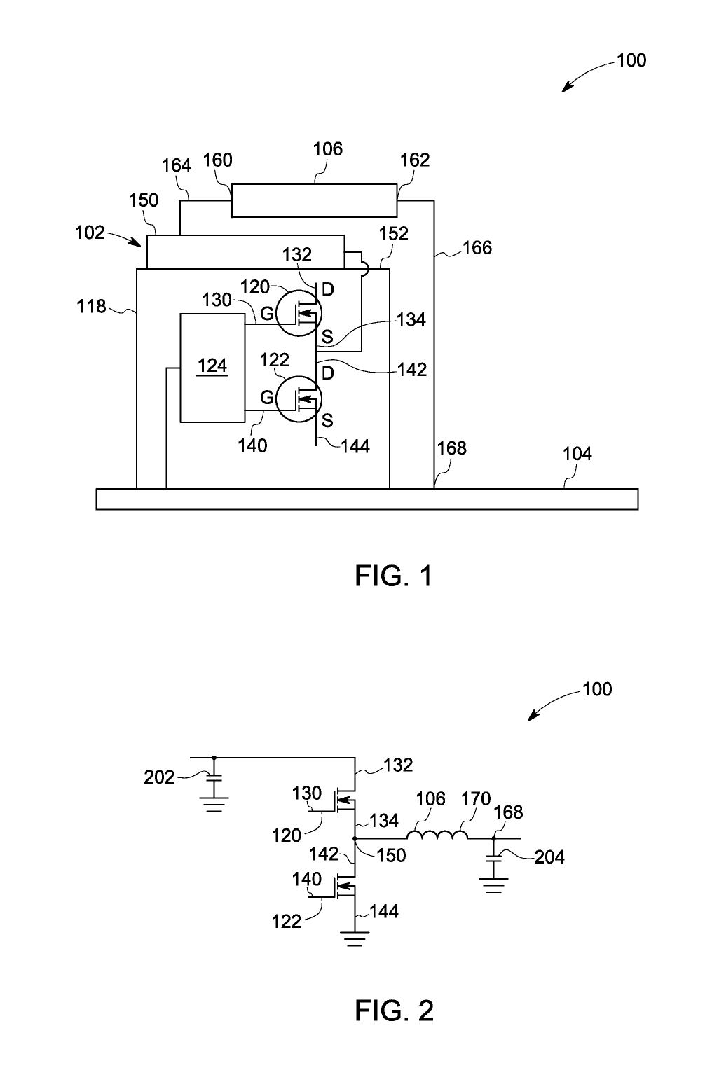

FIG. 1 is a schematic diagram of an exemplary power train assembly 100. Power train assembly 100 includes a component package 102, a printed circuit board (PCB) 104, and a component 106 electrically coupled between component package 102 and PCB 104.

In the exemplary embodiment, power train assembly 100 is implemented in a high density power converter, such as point of load converter, a DC to DC converter, a buck synchronous switching regulator, and/or any other suitable power conversion device where space limitations may be present. Alternatively, power train assembly 100 may be implemented in any electrical architecture that enables power train assembly 100 to function as described herein.

Component package 102 includes circuitry 118 including a first transistor 120, a second transistor 122, and a driver circuit 124, in the exemplary embodiment. First transistor 120 includes a first gate 130, a first drain 132, and a first source 134. Second transistor 122 includes a second gate 140, a second drain 142, and a second source 144. First source 134 is electrically coupled to second drain 142. In the exemplary embodiment, component package 102 is a semiconductor package, and first and second transistors 120 and 122 are both metal-oxide-semiconductor field-effect transistors (MOSFETs), with first transistor 120 functioning as a control FET and second transistor 122 functioning as a synchronous FET. Alternatively, first and second transistors 120 and 122 may be any transistors that enable component package 102 to function as described herein.

In the exemplary embodiment, driver circuit 124 is electrically coupled to PCB 104, first gate 130, and second gate 140. Driver circuit 124 controls operation of first and second transistors 120 and 122. In the exemplary embodiment, first and second transistors 120 and 122 are alternatively turned on and off at a high frequency by respective on and off pulses supplied from driver circuit 124 to first and second gates 130 and 140. Alternatively, component package 102 may not include driver circuit 124, or driver circuit 124 may control operation of first and second transistors 120 and 122 in any manner that enables component package 102 to function as described herein.

Component package 102 includes a thermal pad 150. In the exemplary embodiment, thermal pad 150 is coupled to a top surface 152 of circuitry 118. Thermal pad 150 may also be connected to one or more pads (not shown) on a bottom side of component package 102 at PCB 104. Thermal pad 150 facilitates dissipating heat generated by circuitry 118 and may be, for example, a copper clip. Alternatively, thermal pad 150 may be made of any material that enables component package 102 to function as described herein.

In the exemplary embodiment, thermal pad 150 is electrically coupled to first source 134 and second drain 142, and component 106 is electrically coupled between thermal pad 150 and PCB 104. Accordingly, in addition to dissipating heat from circuitry 118, thermal pad 150 serves as an electrical connection in power train assembly 100.

Component 106 is an inductor in the exemplary embodiment. Alternatively, component 106 may be any suitable electrical component that enables power train assembly 100 to function as described herein. For example, in at least some embodiments, component 106 is a transformer winding. Component 106 includes a first terminal 160 and a second terminal 162. A first lead 164 extends between first terminal 160 and thermal pad 150, and a second lead 166 extends between second terminal 162 and a connection point 168 on PCB 104. In the exemplary embodiment, first and second leads 164 and 166 are soldered to thermal pad 150 and connection point 168, respectively.

Multiple orientations of component 106, first lead 164, and/or second lead 166 with respect to component package 102 and PCB 104 are possible, as will be evident from the embodiments described herein. For example, reducing the distance covered by first and second leads 164 and 166 reduces the size of an effective antenna formed by power train assembly 100. That is, an orientation of power train assembly 100 causes electro-magnetic phenomena that may impact operation of power train assembly 100.

In the exemplary embodiment, as shown in FIG. 1, relative to PCB 104, component 106 is positioned to substantially overlap component package 102. Further, component 106 is oriented substantially parallel to PCB 104. Accordingly, the combination of component package 102 and component 106 conserves board space on PCB 104.

FIG. 2 is a circuit diagram of power train assembly 100. As shown in FIG. 2, first and second transistors 120 and 122 are electrically coupled to component 106 through thermal pad 150. As described above, component 106 is an inductor 170 in the exemplary embodiment. An input capacitor 202 is electrically coupled to first drain 132, and an output capacitor 204 is electrically coupled to component 106. Output capacitor 204 may be electrically coupled to component 106 through, for example, PCB 104.

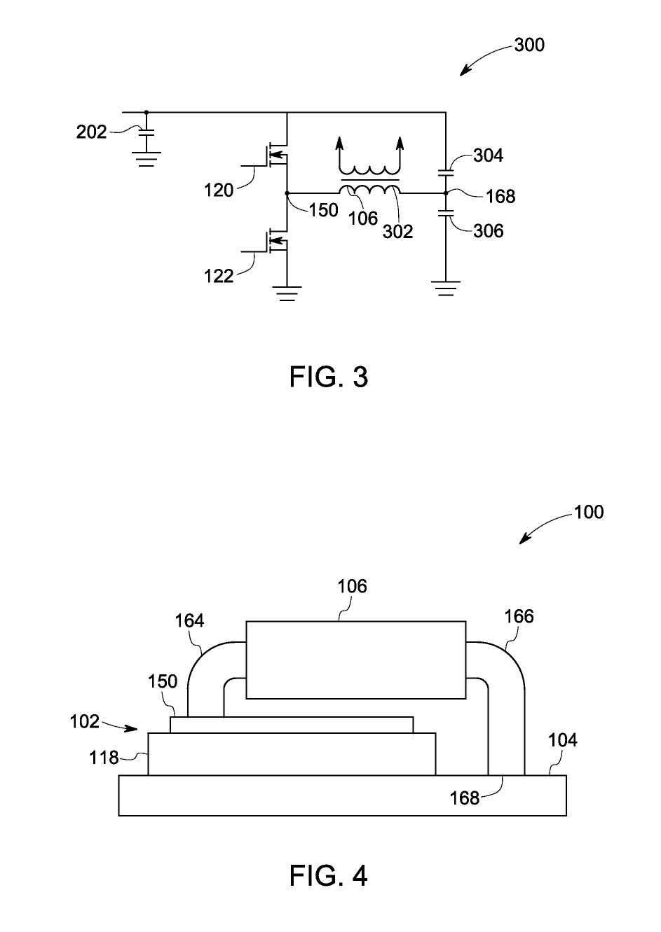

FIG. 3 is a circuit diagram of an alternative power train assembly 300. Unless specified, alternative power train assembly 300 is substantially similar to power train assembly 100 (shown in FIGS. 1 and 2). In power train assembly 300, component 106 is a transformer winding 302. A first capacitor 304 and a second capacitor 306 are electrically coupled to transformer winding 302. First and second capacitors 304 and 306 may be electrically coupled to transformer winding 302 through, for example, PCB 104. Power train assembly 300 forms a half bridge converter.

FIG. 4 is a diagram of power train assembly 100. Component 106 is electrically coupled to thermal pad 150 using first lead 164, and electrically coupled to PCB 104 at connection point 168 using second lead 166. For clarity, the internal connections of component package (e.g., the connection between first source 134, second drain 142, and thermal pad 150) are not shown.

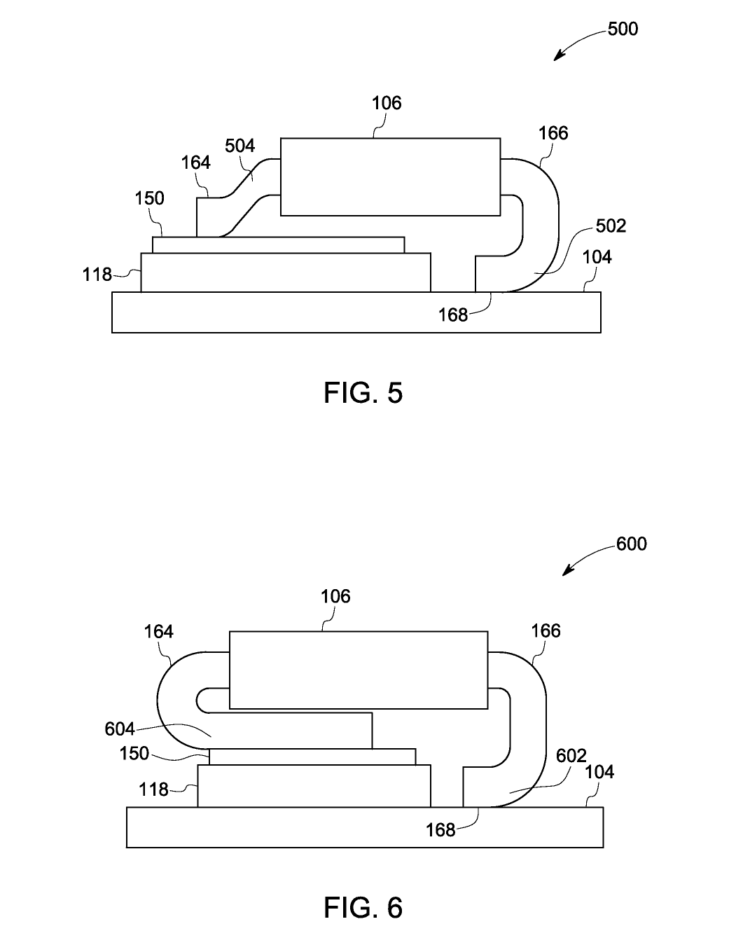

FIG. 5 is a diagram of an alternative power train assembly 500. Unless specified, alternative power train assembly 500 is substantially similar to power train assembly 100 (shown in FIG. 4). In power train assembly 500, second lead 166 has an “L”-shaped bend 502 at connection point 168 such that at least a portion of second lead 166 is bent under component 106. Alternatively, second lead 166 may have a bend that is not under component 106 and/or may be bent outwards with respect to component 106. First lead 164 has an “S”-shaped bend 504 in the exemplary embodiment.

FIG. 6 is a diagram of an alternative power train assembly 600. Unless specified, alternative power train assembly 600 is substantially similar to power train assembly 100 (shown in FIG. 4). In power train assembly 600, second lead 166 has an “L”-shaped bend 602 at connection point 168 such that at least a portion of second lead 166 is bent under component 106. Alternatively, second lead 166 may have a bend that is not under component 106 and/or may be bent outwards with respect to component 106. First lead 164 has an “L”-shaped bend 604 at thermal pad 150 such that at least a portion of first lead 164 is bent under component 106.

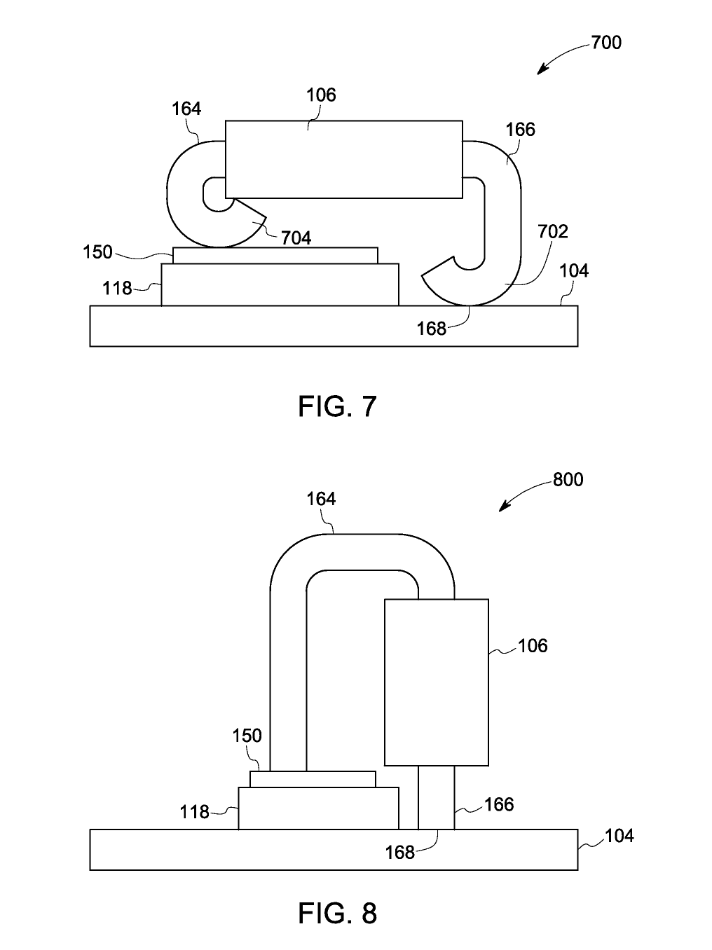

FIG. 7 is a diagram of an alternative power train assembly 700. Unless specified, alternative power train assembly 700 is substantially similar to power train assembly 100 (shown in FIG. 4). In power train assembly 700, second lead 166 has a curled end 702 at connection point 168 such that at least a portion of second lead 166 is bent under component 106. Alternatively, second lead 166 may have a bend that is not under component 106 and/or may be bent outwards with respect to component 106. First lead 164 has a curled end 704 at thermal pad 150 such that at least a portion of first lead 164 is bent under component 106.

FIG. 8 is a diagram of an alternative power train assembly 800. Unless specified, alternative power train assembly 800 is substantially similar to power train assembly 100 (shown in FIG. 4). In power train assembly 800, component 106 is oriented substantially perpendicular to PCB 104, conserving board space of PCB 104 and increasing a vertical profile of power train assembly 800. As shown in FIG. 8, component 106 is oriented to overlap at least a portion of circuitry 118. Alternatively, component 106 may be oriented to not overlap circuitry 118.

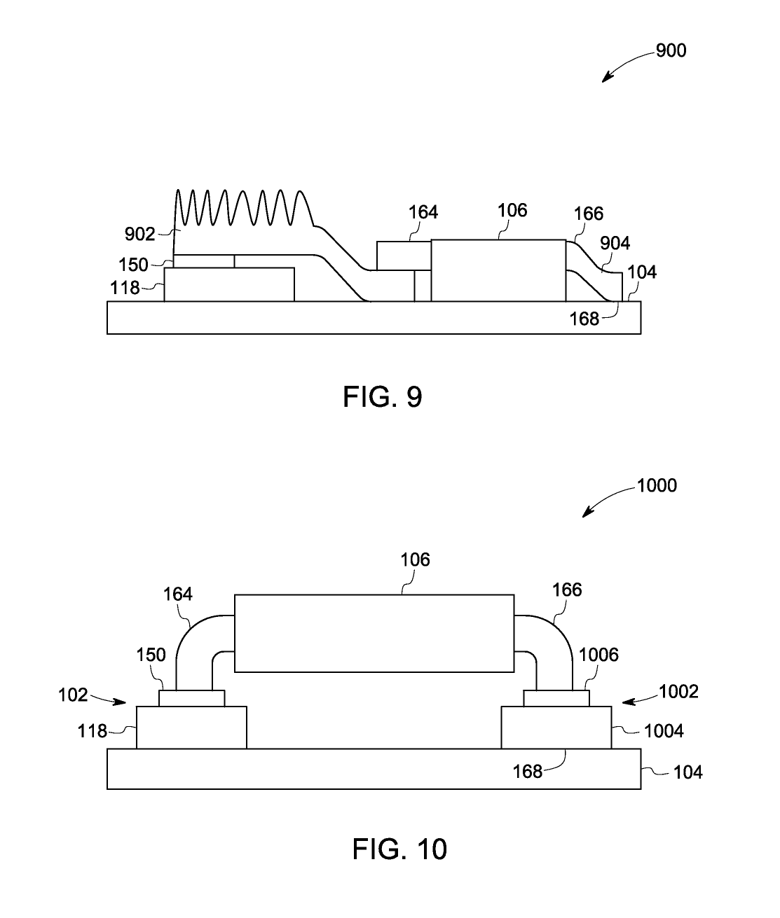

FIG. 9 is a diagram of an alternative power train assembly 900. Unless specified, alternative power train assembly 900 is substantially similar to power train assembly 100 (shown in FIG. 4). In power train assembly 900, a heat-sink 902 is coupled between first lead 164 and thermal pad 150. Heat-sink 902 further facilitates dissipating heat and may be, for example, a mass of copper. As shown in FIG. 9, heat-sink 902 may be shaped to increase a surface area of the heat-sink 902. Second lead 166 has an “S”-shaped bend 904 at connection point 168. Power train assembly 900 has a relatively low vertical profile.

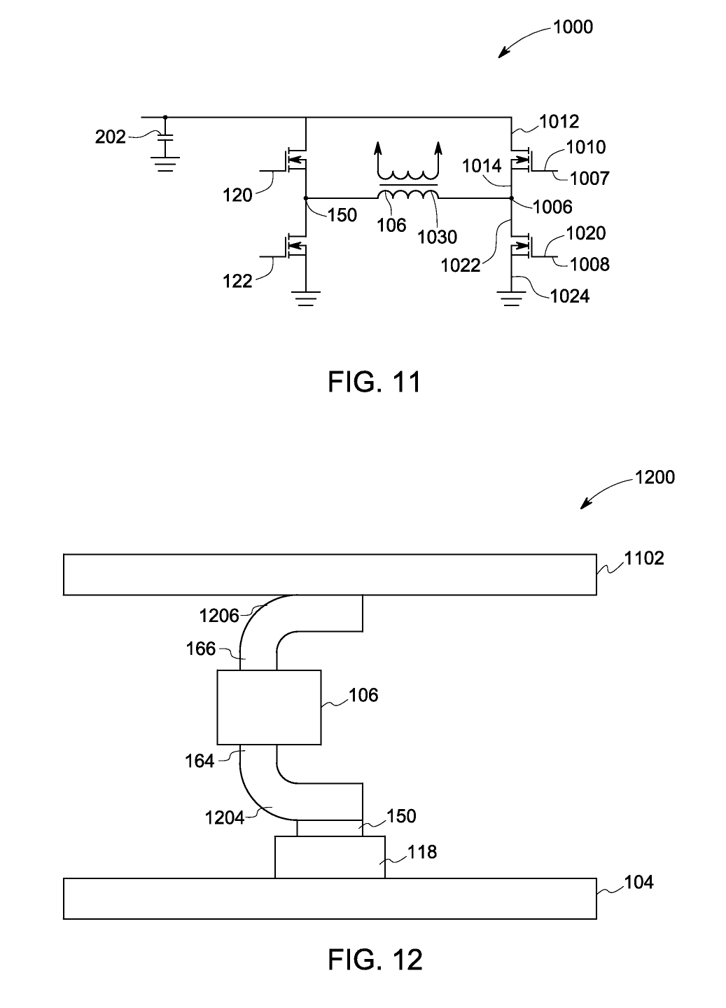

FIG. 10 is a diagram of an alternative power train assembly 1000. FIG. 11 is a circuit diagram of power train assembly 1000. Unless specified, alternative power train assembly 1000 is substantially similar to power train assembly 100 (shown in FIG. 4). Power train assembly 1000 forms a full bridge converter. In power train assembly 1000, component 106 is electrically coupled to a second component package 1002, instead of PCB 104.

Second component package 1002 is substantially similar to component package 102 and includes second circuitry 1004 and a second thermal pad 1006. Second circuitry 1004 includes a first transistor 1007 and a second transistor 1008. First transistor 1007 includes a first gate 1010, a first drain 1012, and a first source 1014. Second transistor 1008 includes a second gate 1020, a second drain 1022, and a second source 1024. As shown in FIG. 11, component 106 is electrically coupled to first source 1014 and second drain 1022 via second thermal pad 1006. Component 106 is a transformer winding 1030 in power train assembly 1000.

FIG. 12 is a diagram of an alternative power train assembly 1200. Unless specified, alternative power train assembly 1200 is substantially similar to power train assembly 100 (shown in FIG. 4). In power train assembly 1200, component 106 is electrically coupled to a second PCB 1102, instead of PCB 104. In the exemplary embodiment, second PCB 1102 is oriented substantially parallel to PCB 104. Component 106 is oriented substantially parallel to PCBs 1102 and 104, and may reduce a vertical space between PCBs 1102 and 104. First lead 164 has an “L”-shaped bend 1204 at thermal pad 150 such that at least a portion of first lead 164 is bent under component 106, and second lead 166 has an “L”-shaped bend 1206 at second PCB 1102 such that at least a portion of second lead 166 is bent over component 106, which may further reduce the vertical space between PCBs 1102 and 104.

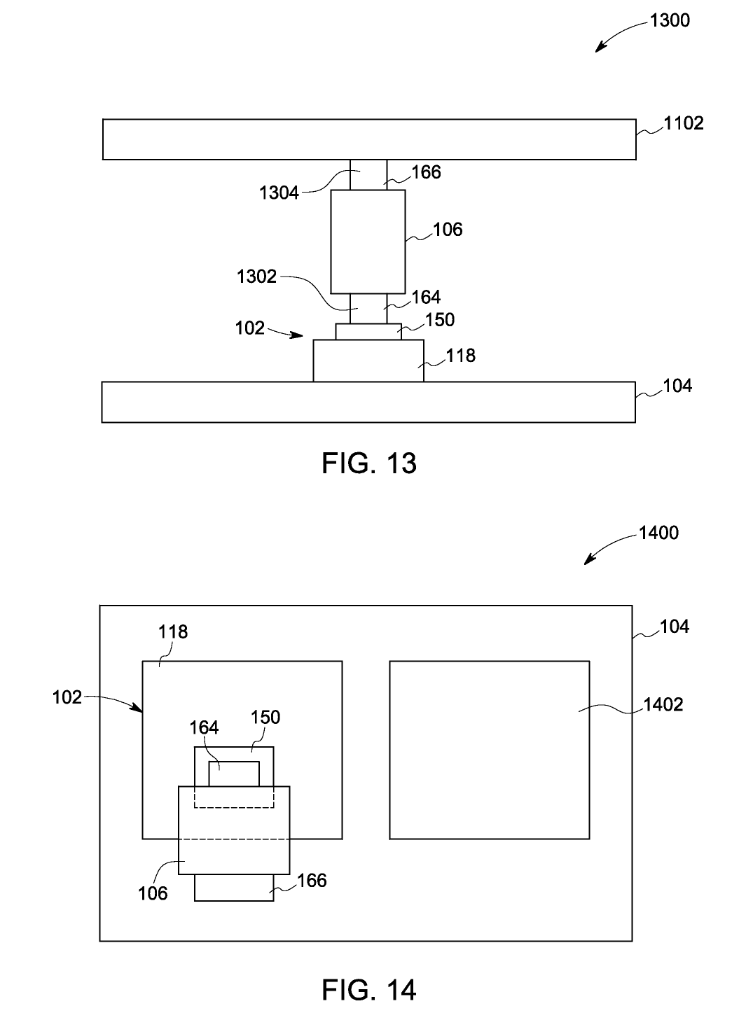

FIG. 13 is a diagram of an alternative power train assembly 1300. Unless specified, alternative power train assembly 1300 is substantially similar to power train assembly 1200 (shown in FIG. 12). In power train assembly 1300, component 106 is oriented vertically with respect to PCBs 1102 and 104, increasing the vertical space between PCBs 1102 and 104. First lead 164 forms a butt joint 1302 (i.e., a joint without any bend) and second lead 166 forms a butt joint 1304. The increased vertical space may facilitate mechanical construction and/or increased heat dissipation from component package 102.

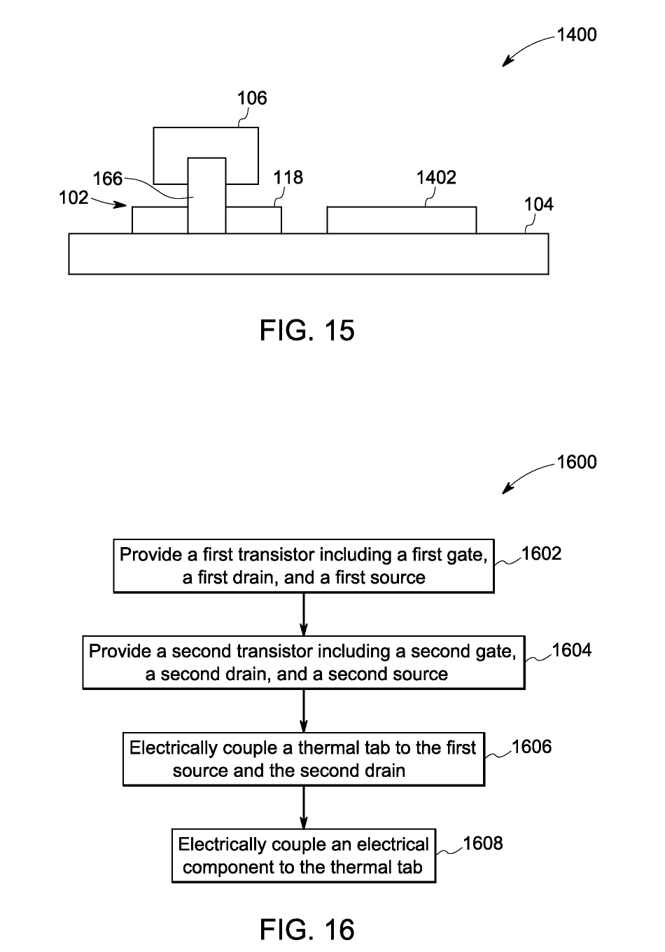

FIG. 14 is a plan view of an alternative power train assembly 1400. FIG. 15 is a side view of power train assembly 1400. Unless specified, alternative power train assembly 1400 is substantially similar to power train assembly 100 (shown in FIG. 4). Power train assembly 1400 includes a second component package 1402. Similar to component package 102, second component package 1402 may include a thermal pad and a plurality of transistors (not shown). In power train assembly 1400, component 106 is electrically coupled between component package 102 and PCB 104. To form a full bridge converter, second component package 1402 may be electrically coupled to component 106 through PCB 104.

FIG. 16 is a flowchart of an exemplary method 1600 for assembling a power train assembly, such as power train assembly 100 (shown in FIG. 1). A first transistor, such as first transistor 120 is provided 1602. The first transistor includes a first gate, a first drain, and a first source. A second transistor, such as second transistor 122 (shown in FIG. 1) is provided 1604. The second transistor includes a second gate, a second drain, and a second gate. The first transistor and second transistor are included in a component package.

A thermal pad, such as thermal pad 150 (shown in FIG. 1), is electrically coupled 1606 to the first source and the second drain. The thermal tab is also included in the component package. An electrical component, such as component 106 (shown in FIG. 1) is electrically coupled 1608 to the thermal tab. The electrical component may include, for example, an inductor or a transformer winding.

Exemplary embodiments of power train assemblies are described herein. As compared to at least some known power train assemblies, in the systems and methods described herein, a thermal pad is utilized as an electrical connection between transistors in a component package and at least one additional electrical component such that the at least one additional electrical component is directly coupled to the thermal pad (i.e., not coupled to the thermal pad through a PCB). Using the thermal pad as an electrical connection reduces the number of connections required in at least some known power train assemblies. Further, using the systems and methods described herein, the at least one additional electrical component may be oriented to reduce board space on a PCB.

The order of execution or performance of the operations in the embodiments of the invention illustrated and described herein is not essential, unless otherwise specified. That is, the operations may be performed in any order, unless otherwise specified, and embodiments of the invention may include additional or fewer operations than those disclosed herein. For example, it is contemplated that executing or performing a particular operation before, contemporaneously with, or after another operation is within the scope of aspects of the invention.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A power train assembly comprising:
a component package comprising:
a first transistor comprising a first gate, a first drain, and a first source;
a second transistor comprising a second gate, a second drain, and a second source; and
a thermal pad configured to dissipate heat generated in said component package, wherein said thermal pad is electrically coupled to said first source and said second drain;
a printed circuit board (PCB) electrically coupled to said component package; and
an electrical component electrically coupled directly to a top surface of said thermal pad in a first plane and to said PCB in a second plane that is parallel to said first plane, wherein the electrical component is external to the component package.

2. A power train assembly in accordance with claim 1, wherein said electrical component comprises an inductor.

3. A power train assembly in accordance with claim 1, wherein said electrical component comprises a transformer winding.

4. A power train assembly in accordance with claim 1, further comprising:
a first lead electrically coupling a first terminal of said electrical component directly to said thermal pad in said first plane; and
a second lead electrically coupling a second terminal of said electrical component to a connection point of said PCB in said second plane.

5. A power train assembly in accordance with claim 4, wherein at least one of said first lead and said second lead is bent under said electrical component.

6. A power train assembly in accordance with claim 1, wherein at least a portion of said electrical component overlaps said component package to conserve board space on said PCB.

7. A power train assembly in accordance with claim 1, further comprising an additional component package electrically coupled to said electrical component through said PCB, wherein said component package, said electrical component, and said additional component package form a full bridge converter.

8. A power train assembly in accordance with claim 1, wherein said thermal pad is a copper clip.

9. A component package comprising:
a first transistor comprising a first gate, a first drain, and a first source;
a second transistor comprising a second gate, a second drain, and a second source; and
a thermal pad configured to dissipate heat generated in said component package, wherein said thermal pad is electrically coupled to said first source and said second drain and directly coupled, at a top surface of said pad, to at least one additional electrical component.

10. A component package in accordance with claim 9, wherein said first and second transistors each comprise a metal-oxide-semiconductor field-effect transistor.

11. A component package in accordance with claim 9, wherein said thermal pad is a copper clip.

12. A component package in accordance with claim 9, further comprising a driver circuit electrically coupled to said first gate and said second gate, said driver circuit configured to switch said first and second transistors on and off at a high frequency.

13. A component package in accordance with claim 9, further comprising a heat sink coupled to said thermal pad.

14. A component package in accordance with claim 9, wherein said component package forms at least a portion of a buck synchronous switching regulator.

15. A method of assembling a power train assembly, said method comprising:
electrically coupling a component package to a printed circuit board (PCB), the component package including a first transistor including a first gate, a first drain, and a first source, a second transistor including a second gate, a second drain, and a second source, and a thermal tab electrically coupled to the first source and the second drain; and
electrically coupling an electrical component directly to a top surface of the thermal pad in a first plane and to the PCB in a second plane that is parallel the first plane, the electrical component external to the component package.

16. A method in accordance with claim 15, further comprising:
electrically coupling the electrical component between the thermal tab and the PCB.

17. A method in accordance with claim 15, wherein electrically coupling an electrical component comprises electrically coupling at least one of an inductor and a transformer winding directly to the thermal tab.

18. A method in accordance with claim 15, further comprising:
providing a second component package including a second thermal tab; and
electrically coupling the electrical component between the thermal tab and the second thermal tab.

19. A method in accordance with claim 15, further comprising:
electrically coupling the electrical component between the thermal tab and a second PCB.

20. A method in accordance with claim 15, wherein electrically coupling a component package comprises electrically coupling a semiconductor package.
